(19) United States
(12) Patent Application Publication
(10) Pub. No.: US 2023/0285897 A1
(43) Pub. Date: Sep. 14, 2023

(54) GAS PURIFYING FILTER AND SUBSTRATE TREATMENT APPARATUS INCLUDING THE SAME

(71) Applicant: Samsung Electronics Co., Ltd., Suwon-si (KR)

(72) Inventors: Mira Park, Hwaseong-si (KR); Hoigu Jang, Cheongju-si (KR); Jiwoong Shin, Hwaseong-si (KR); Kieung Lee, Cheongju-si (KR); Yeonju Ji, Cheongju-si (KR); Jiyoung Kim, Hwaseong-si (KR); Joonseok Min, Cheongju-si (KR); Dusik Bae, Hwaseong-si (KR); Dongil Shin, Cheongju-si (KR); Sangyoon Shin, Seoul (KR); Minseon Lee, Seoul (KR); Seungbin Lee, Cheongju-si (KR)

(73) Assignees: Samsung Electronics Co., Ltd., Suwon-si (KR); EcoPro HN Co., Ltd., Cheongju-si (KR)

(21) Appl. No.: 18/100,209

(22) Filed: Jan. 23, 2023

(30) Foreign Application Priority Data
Jan. 25, 2022 (KR) 10-2022-0010424

(51) Int. Cl. B01D 53/82; B01D 53/04; B01D 53/72; G03F 7/20; B01J 20/20; B01J 20/18; B01J 20/26; B01J 20/28; H01L 21/67

(52) U.S. Cl. CPC B01D 53/82; B01D 53/04; B01D 53/72; B01J 20/18; B01J 20/20; B01J 20/261; B01J 20/28004; B01J 20/28035; B01J 20/2804; B01J 20/2808; B01J 20/28083; G03F 7/70858; H01L 21/67017; B01D 2251/512; B01D 2253/102; B01D 2253/108; B01D 2253/206; B01D 2253/25; B01D 2253/304; B01D 2253/308; B01D 2257/556

(57) ABSTRACT

A gas purifying filter includes a first gas permeable body having a gas inlet surface; a first adsorption layer disposed on the first gas permeable body and including activated carbon on which a phosphoric acid-based compound satisfying the following Formula 1 is supported; a second adsorption layer disposed on the first adsorption layer and including a hydrophobic zeolite having a SiO₂/Al₂O₃ value of about 50 or more; and a second gas permeable body disposed on the second adsorption layer and having a gas outlet surface,

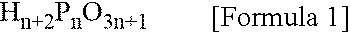

where n is an integer greater than or equal to 1.

### CROSS-REFERENCE TO RELATED APPLICATION(S)

This application claims benefit of priority to Korean Patent Application No. 10-2022-0010424 filed on Jan. 25, 2022 in the Korean Intellectual Property Office, the disclosure of which is incorporated herein by reference in its entirety.

### BACKGROUND

The present inventive concept relates to a gas purifying filter and a substrate treatment apparatus including the same.

In general, semiconductor manufacturing facilities may include a fabrication process for forming an electrical circuit on a silicon wafer used as a semiconductor substrate, an electrical die sorting (EDS) process for inspecting electrical characteristics of semiconductor devices formed in the fabrication process, and a package assembly process for encapsulating and individualizing semiconductor devices with a synthetic resin.

Thereamong, a number of unit processes such as a deposition process, a photolithography process, an etching process, a cleaning process, and the like may be performed in the fabrication process. Each unit process should be performed in a clean space in which contaminants such as particles or the like are strictly controlled. For example, in an exposure facility for exposing a photoresist formed on a wafer, high-purity air should be supplied to front and rear ends of a reduction lens for reducing and projecting a predetermined pattern formed on a reticle.

### SUMMARY

An aspect of the present inventive concept is to provide a gas purifying filter preventing contamination in a semiconductor manufacturing facility.

Another aspect of the present inventive concept is to provide a substrate treatment apparatus preventing contamination in a semiconductor manufacturing facility and having improved productivity.

According to an aspect of the present inventive concept, a gas purifying filter includes a first gas permeable body having a gas inlet surface; a first adsorption layer disposed on the first gas permeable body and including activated carbon on which a phosphoric acid-based compound satisfying the following Formula 1 is supported; a second adsorption layer disposed on the first adsorption layer and including a hydrophobic zeolite having a SiO₂/Al₂O₃ value of about 50 or more; and a second gas permeable body disposed on the second adsorption layer and having a gas outlet surface. Note that as disclosed herein, when one element is “on” another element, this can be directly on, or indirectly on (with intervening structure therebetween).

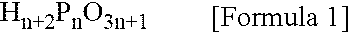

where n is an integer greater than or equal to 1.

According to an aspect of the present inventive concept, a substrate treatment apparatus includes a working region accommodating a spinner and a scanner; a lower plenum chamber disposed below the working region and accommodating exhaust gas discharged from the spinner; and an air control cabinet disposed in the lower plenum chamber below the scanner and including a first filter, wherein the first filter includes a first gas permeable body having a gas inlet surface; a first adsorption layer disposed on the first gas permeable body and including activated carbon on which a phosphoric acid-based compound satisfying the following Formula 1 is supported; a second adsorption layer disposed on the first adsorption layer and including a hydrophobic zeolite having a SiO₂/Al₂O₃ value of about 50 or more; and a second gas permeable body disposed on the second adsorption layer and having a gas outlet surface.

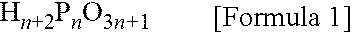

where n is an integer greater than or equal to 1.

According to an aspect of the present inventive concept, a gas purifying filter includes a first adsorption layer including a hydroxyl group on a surface thereof and including activated carbon having a pore with a size of about 5 Å to about 20 Å; and a second adsorption layer disposed on the first adsorption layer and including a hydrophobic zeolite having a pore with a size of about 5 to about 8 Å, wherein the hydrophobic zeolite comprises about 5 to about 20 wt%, based on a total weight of the activated carbon and the hydrophobic zeolite.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a schematic configuration diagram illustrating a substrate treatment apparatus according to example embodiments.

FIGS. 2A to 2C are cross-sectional views illustrating a semiconductor photo process according to example embodiments.

FIG. 3 is a perspective and cross-sectional view illustrating a gas purifying filter according to example embodiments.

FIG. 4 is a cross-sectional view illustrating a gas purifying filter according to example embodiments.

FIG. 5 is a cross-sectional view illustrating a gas purifying filter according to example embodiments.

FIG. 6 is a perspective view illustrating a gas purifying filter according to example embodiments.

FIG. 7A is a perspective view illustrating a gas purifying filter according to example embodiments, FIG. 7B is a cross-sectional view illustrating a gas purifying filter according to example embodiments, and FIG. 7C is a partial perspective view illustrating a gas purifying filter according to example embodiments.

FIG. 8 is a process flow diagram schematically illustrating a method of manufacturing a gas purifying filter according to example embodiments.

FIG. 9 is a process flow diagram schematically illustrating a method of manufacturing a gas purifying filter according to example embodiments.

FIG. 10 is a schematic configuration diagram illustrating a substrate treatment apparatus according to example embodiments.

### DETAILED DESCRIPTION

Hereinafter, example embodiments of the present inventive concept will be described with reference to the accompanying drawings.

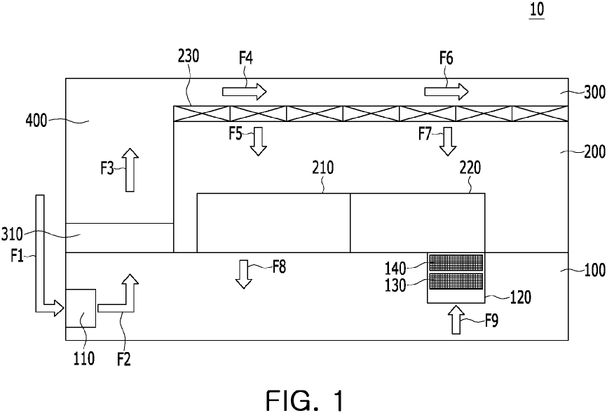

Referring to FIG. 1, a substrate treatment apparatus according to example embodiments will be described. FIG. 1 is a schematic configuration diagram illustrating a substrate treatment apparatus according to example embodiments.

Referring to FIG. 1, a substrate treatment apparatus 10 may include a lower plenum chamber 100, a working region 200, an upper plenum chamber 300, and a circulation passage 400.

In the working region 200, a plurality of unit processes (e.g., a deposition process, a photolithography process, an etching process, a cleaning process, and the like) for manufacturing a semiconductor, may be performed. The working region 200 may provide a clean space in which the unit processes for manufacturing the semiconductor are performed.

The upper plenum chamber 300 for supplying purified air to the working region 200 may be disposed on the working region 200. The purified air may pass through the working region 200, may flow in a downward direction, and may move to the lower plenum chamber 100 disposed below the working region 200. The gas discharged from the working region 200 to the lower plenum chamber 100 may move to the upper plenum chamber 300 through the circulation passage 400, and may reflow into the working region 200.

Arrows F1 to F9 illustrated in FIG. 1 illustrate the flow of gas in the substrate treatment apparatus 10. Hereinafter, gas flow in the substrate treatment apparatus 10 will be described in detail.

As illustrated in FIG. 1, fresh air may flow into the lower plenum chamber 100 from an outside of the substrate treatment apparatus 10 (F1). The lower plenum chamber 100 may include an air inlet 110 introducing the fresh air from the outside of the substrate treatment apparatus 10.

The air inlet 110 may accommodate the fresh air into the lower plenum chamber 100, and may move the air toward the circulation passage 400 (F2). As necessary, the air inlet 110 may include a circulation pump. As the fresh air moves in an upward direction from the air inlet 110, some of the gas accommodated in the lower plenum chamber 100 may move in the upward direction together therewith. A dry coil 310 may be disposed between the lower plenum chamber 100 and the circulation passage 400. Mixed gas moving from the lower plenum chamber 100 to the circulation passage 400 may pass through the dry coil 310. In the working region 200 in which the semiconductor manufacturing process is performed, precise control of temperature and humidity conditions may be required in proportion to precision of a product. The dry coil 310 may perform a heat exchange process for gas mixed with fresh air flowing from the outside and exhaust gas discharged from the working region 200. The dry coil 310 may continuously maintain the temperature and humidity conditions required in the working region 200.

Gas passing through the dry coil 310 may flow into the circulation passage 400 (F3). The gas may move along the circulation passage 400 in the upward direction. Thereafter, the gas may move to the upper plenum chamber 300 disposed on the working region 200 (F4 and F6).

Gas moved to the upper plenum chamber 300 may flow into the working region 200 (F5 and F7).

Fan filter units 230 may be disposed on a ceiling of the working region 200. Gas accommodated in the upper plenum chamber 300 may flow into the working region 200 through the fan filter units 230. Each of the fan filter units 230 may include a fan (not illustrated) and one or more filters (not illustrated). In an example embodiment, one or more filters may be provided below the fan.

Gas of the upper plenum chamber 300 may flow into the working region 200 by an operation of the fan of the fan filter units 230. In an example embodiment, the fan may include an impeller creating flow of the gas. The impeller may be, for example, a rotating cylinder having a plurality of blades arranged at equal intervals in a circumferential direction. The one or more filters may remove contaminants included in the gas flowing from the upper plenum chamber 300. In an example embodiment, the filters may be a high efficiency particulate air (HEPA) filter, an ultra-low penetration air (ULPA) filter or a chemical filter (CF). Fresh air from which contaminants are removed from the upper plenum chamber 300 through the fan filter units 230 may flow into the working region 200.

A plurality of processes for manufacturing a semiconductor may be performed in the working region 200. For example, a plurality of unit processes (e.g., a deposition process, a photolithography process, an etching process, a cleaning process, and the like) may be performed in the working region 200. A plurality of facilities for performing the unit processes may be provided in the working region 200.

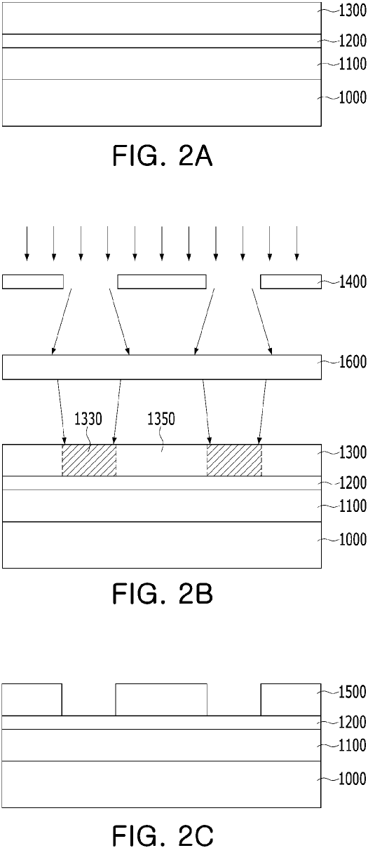

In an example embodiment, a spinner 210 and a scanner 220 for performing a photolithography process may be provided in the working region 200. In the spinner 210, a photoresist application process and a developing process may be performed. In the scanner 220, an exposure process of a photoresist using a reduction lens (1600 in FIG. 2B) or the like may be performed.

Air in the working region 200 may move to the lower plenum chamber 100 disposed below the working region 200 (F8).

Gas discharged from the working region 200 may be mixed with fresh air flowing from the air inlet 110, may pass through the dry coil 310, and may flow into the circulation passage 400 (F3). Mixed gas flowing into the circulation passage 400 may move to the upper plenum chamber 300 (F4 and F6), may pass through the fan filter units 230, and may be then reflowing into the working region 200 (F5 and F7). As above, exhaust gas discharged from the working region 200 may be purified by circulating in the substrate treatment apparatus 10, and may flow into the working region 200 again.

Some of gas flowing into the lower plenum chamber 100 may be directly flowing into the working region 200 without passing through the circulation path described above (F9). The gas in the lower plenum chamber 100 may contain contaminants, due to unintended contaminants or the like in fresh air flowing from the air inlet 110. When the gas in the lower plenum chamber 100 flowing into the scanner 220 without passing through the circulation path, contaminants may flow into the scanner 220. For example, a low molecular weight silicon (Si)-based contaminant, for example, trimethylsilanol (TMS) may be included in the gas flowing into the scanner 220.

A surface of a reduction lens (1600 in FIG. 2B) in the scanner 220 may be contaminated by trimethylsilanol contained in the inflow gas. The trimethylsilanol may have a size as small as about 4.2 Å to about 4.9 Å and a molecular weight as low as about 90.2 g/mol, to easily flow into the scanner 220. The trimethylsilanol flowing into the scanner 220 may be decomposed into silicon dioxide (SiO₂) by a light source such as a laser or the like in the scanner. The silicon dioxide (SiO₂) may be attached to the reduction lens (1600 of FIG. 2B) in the scanner 220, and may cause lens hazing. For this reason, precision of an exposure process in the scanner 220 may be lowered, and product defects may occur. Since a lens replacement cycle in the scanner 220 may be shortened, process efficiency may be deteriorated. Though trimethylsilanol is referred to as the contaminant herein, other contaminants can be filtered in this or other processes for example, low molecular weight and low size silanols, e.g. alkoxysilanols other than the mentioned TMS, silanes or other small volatile organic compounds comprising silicon and hydroxyl groups, including halogenated forms of the above, that can form silicon dioxide or other undesirable byproducts. Such other contaminants may have a molecular weight less than 120 g/mol, e.g. less than 100 g/mol, and/or a size less than 8 Å, e.g. less than 6 Å.

A substrate treatment apparatus 10 according to example embodiments of the present inventive concept may include an air control cabinet 120 to prevent contaminants from entering the scanner 220. The air control cabinet 120 may filter air flowing into the scanner 220 from the lower plenum chamber 100, to remove contaminants contained in the air.

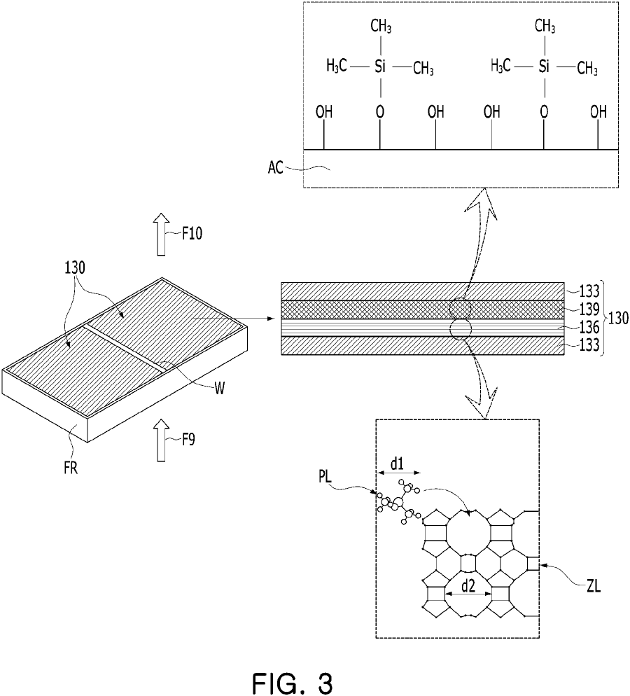

The air control cabinet 120 may include a filter 130. The filter 130 may primarily remove contaminants in exhaust gas flowing from the lower plenum chamber 100. An air control cabinet 120 according to example embodiments of the present inventive concept may include a filter 130 to efficiently remove organic contaminants. The filter 130 may efficiently remove low molecular weight silicon (Si)-based contaminants, for example, TMS. A structure of the filter 130, principle of removing contaminants, or the like will be described later in detail with reference to FIG. 3.

The air control cabinet 120 may further include a filter, in addition to the filter 130. In an example embodiment, the air control cabinet 120 may further include a first filter 130 and a second filter 140.

The second filter 140 may remove remaining contaminants not removed by the first filter 130. For example, the second filter 140 may remove organic or inorganic compounds. In an example embodiment, the second filter 140 may be a hybrid filter including at least one of activated carbon or an ion exchange resin. A material of the second filter 140 is not limited thereto. For example, the second filter 140 may be a chemical filter including a metal oxide powder having harmful gas removal activity.

Air flowing into the air control cabinet 120 from the lower plenum chamber 100 may sequentially pass through the first filter 130 and the second filter 140. As necessary, the air control cabinet 120 may further include a filter, in addition to the first and second filters 130 and 140.

In the embodiment of FIG. 1, sizes of the first filter 130 and the second filter 140 are illustrated as being the same, but the present inventive concept is not limited thereto, and the sizes of the filters may be different from each other. In an example embodiment, a material included in the second filter 140 may be about 10 or more times a material included in the first filter 130. A volume of the second filter 140 may be about 10 or more times a volume of the first filter 130.

A filter 130 according to example embodiments of the present inventive concept may efficiently remove organic contaminants, for example, TMS. Therefore, precision and efficiency in a process of manufacturing a semiconductor, performed in the working region 200, may be improved.

Hereinafter, a photolithography process as an example of a process performed in the working region 200 will be described with reference to FIGS. 1 and 2A to 2C together.

A photolithography process may be performed using the spinner 210 and the scanner 220 in the working region 200. In example embodiments, a photoresist application process (FIG. 2A) and a developing process (FIG. 2C) may be performed by the spinner 210, and a photoresist exposure process (FIG. 2B) may be performed by the scanner 220.

Referring to FIG. 2A, an etching target layer 1100, an anti-reflection layer 1200, and a photoresist layer 1300 may be sequentially formed on a substrate 1000.

As the substrate 1000, a semiconductor substrate, for example, a silicon substrate, a germanium substrate, a silicon-germanium substrate, a silicon-on-insulator (SOI) substrate, a germanium-on-insulator (GOI) substrate, or the like may be used. In an example embodiment, the substrate 1000 may include a III-V group compound, such as GaP, GaAs, GaSb, or the like.

The etching target layer 1100 may refer to a layer in which an image is transferred from a photoresist pattern and converted into a predetermined pattern. The etching target layer 1100 may be formed to include an insulating material such as silicon oxide, silicon nitride, silicon oxynitride, or the like. A material of the etching target layer 1100 is not limited thereto. In another embodiment, the etching target layer 1100 may be formed to include a conductive material such as a metal, a metal nitride, a metal silicide, or a metal silicide nitride layer, or may be formed to include a semiconductor material such as polysilicon.

The etching target layer 1100 may be formed by, for example, at least one of a chemical vapor deposition (CVD) process, a plasma enhanced chemical vapor deposition (PECVD) process, a low pressure chemical vapor deposition (LPCVD) process, a high density plasma chemical vapor deposition (HDP-CVD) process, a spin coating process, a sputtering process, an atomic layer deposition (ALD) process, or a physical vapor deposition (PVD) process.

The anti-reflection layer 1200 may be formed using an aromatic organic material (e.g., phenol resin, novolac resin, or the like) or an inorganic material (e.g., silicon oxynitride or the like). The anti-reflection layer 1200 may be formed using a layer coating process such as a spin coating process, a dip coating process, a spray coating process, or the like. In some embodiments, formation of the anti-reflection layer 1200 may be omitted.

The photoresist layer 1300 may be formed using an organic material (e.g., hexamethyldisiloxane (hereinafter, ‘HMDSO’)). The photoresist layer 1300 may be formed through a film coating process such as a spin coating process, a dip coating process, a spray coating process, or the like. In some embodiments, the photoresist layer 1300 may be formed by applying a photoresist composition to form a preliminary photoresist layer, and performing a curing process such as a baking process thereon.

Referring to FIG. 2B, an exposure process may be performed on the photoresist layer 1300.

An exposure mask 1400 may be disposed on or above the photoresist layer 1300, and light may be irradiated through an opening included in the exposure mask 1400. The light passing through the opening may be spread in all directions by diffraction. A reduction lens 1600 may be disposed between the substrate 1000 and the exposure mask 1400. The spread light that has passed through the exposure mask 1400 may be collected by the reduction lens 1600 to accurately reflect a fine shape of the exposure mask 1400 on the substrate 1000.

A light source used in an exposure process is not particularly limited. As the light source used in the exposure process, for example, ArF, KrF, electron beam, I-line, extreme ultraviolet (EUV) light source, or the like may be used.

The photoresist layer 1300 may be divided into an exposed portion 1330 and a non-exposed portion 1350 by the exposure process. The exposed portion 1330 may react with the light source to change, for example, a chemical structure.

Referring to FIG. 2C, the exposed portion (1330 of FIG. 2B) of the photoresist layer (1300 of FIG. 2B) may be selectively removed by a developing process. Therefore, a photoresist pattern 1500 may be defined by the non-exposed portion (1350 of FIG. 2B) of the photoresist layer (1300 of FIG. 2B) remaining on the etching target layer 1100 or the anti-reflection layer 1200.

In example embodiments, the coating process illustrated in FIG. 2A and the developing process illustrated in FIG. 2C may be performed in the spinner 210, and the exposure process illustrated in FIG. 2B may be performed in the scanner 220, but is not limited thereto. In other embodiments, the coating process illustrated in FIG. 2A may be performed in the spinner 210, the exposure process illustrated in FIG. 2B may be performed in the scanner 220, and the developing process illustrated in FIG. 2C may be performed in a separate facility.

Referring to FIGS. 1 and 2A to 2C together, when a contaminant is included in the gas flowing into the scanner 220 along the F9 path, the reduction lens 1600 in the scanner 220 may be contaminated. For example, when gas containing a low molecular weight silicon (Si)-based contaminant such as TMS or the like flows into the scanner 220, the TMS may have a size as small as about 4.2 Å to about 4.9 Å, and a molecular weight as low as about 90.2 g/mol. In this case, it may be difficult to remove with general carbon-based filters. When some of the TMS is not purified and flows into the scanner 220, the TMS may be decomposed into silicon dioxide (SiO₂) by the light source in the scanner 220, and may be attached to the reduction lens (1600 of FIG. 2B) in the scanner 220.

In example embodiments of the present inventive concept, the air control cabinet 120 may include the filter 130 illustrated in FIG. 3, to effectively remove a low molecular weight silicon (Si)-based contaminant such as TMS or the like from gas flowing into the scanner 220 in the working region 200. Therefore, haze of the reduction lens 1600 in the scanner 220 may be reduced or prevented.

Hereinafter, a filter 130 according to example embodiments of the present inventive concept will be described with reference to FIG. 3.

The filter 130 may include a first gas permeable body 133, a first adsorption layer 136 disposed on the first gas permeable body 133, a second adsorption layer 139 disposed on the first adsorption layer 136, and a second gas permeable body 133 disposed on the second adsorption layer 139.

Air may flow into the first gas permeable body 133 (F9), may pass through the first adsorption layer 136 and the second adsorption layer 139, and may flow out from the second gas permeable body 133 (F10).

The first and second air permeable bodies 133 may include a material having gas permeability. The first gas permeable body 133 may include, for example, non-woven fabric, filter paper, sponge, fabric, or the like. A contaminant may pass through the first gas permeable body 133, and may be adsorbed to the first and second adsorption layers 136 and 139. The first and second air permeable bodies 133 may pass gases, and may fix the first and second adsorption layers 136 and 139. The first gas permeable body 133 may include a gas inlet surface, and the second gas permeable body 133 may include a gas outlet surface.

According to embodiments, one or more of the first and second air permeable bodies 133 may be omitted. For example, air may flow into the first adsorption layer 136, and may flow out into the second adsorption layer 139.

The first adsorption layer 136 may include activated carbon having a hydroxyl group (—OH) on a surface thereof. The activated carbon may have a phosphoric acid-based compound supported thereon, to form the hydroxyl group on a surface thereof. The phosphoric acid-based compound may have the following [Formula 1]. In [Formula 1], a value of n is an integer greater than or equal to 1. An upper limit of the value of n is not particularly limited, and may be, for example, an integer of 100 or less. In an example embodiment, the phosphoric acid-based compound may include H₄P₂O₇. In addition to pyrophosphoic acid, other examples include orthophosphoric acid, tripolyphosphoric acid, tetrapolyphosphoric acid, etc In another embodiment, the phosphoric acid-based compound may include two or more compounds having different n values.

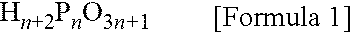

The activated carbon on which the phosphoric acid-based compound contained in the first adsorption layer 136 is supported may physically adsorb and remove contaminants in air. The contaminants may be removed by a pore of the activated carbon. The activated carbon may have a large surface area including the pore in a particle. The activated carbon may remove the contaminants from the air, for example by van der Waals bonds.

The activated carbon on which the phosphoric acid-based compound is supported, included in the first adsorption layer 136, may also chemically remove contaminants in air. As illustrated in FIG. 3, a hydroxyl group on a surface of the activated carbon (AC) may chemically bond with TMS, to remove the TMS from the air. Chemical adsorption may be carried out by a reduction reaction to contaminants. For example, a hydroxyl group may form a covalent bond with TMS, and thus may have superior anchoring power, compared to physical adsorption.

In the activated carbon on which the phosphoric acid-based compound is supported, included in the first adsorption layer 136, the phosphoric acid-based compound may be supported in an amount of about 5 wt% to about 15 wt%, based on 100 wt% of the activated carbon. When an amount of the phosphoric acid-based compound is less than 5 wt%, chemical reaction with contaminants such as TMS or the like by the hydroxyl group of the activated carbon may not be sufficient. When an amount of the phosphoric acid-based compound is 15 wt% or more, the phosphoric acid-based compound may block the pores of the activated carbon. Therefore, physical removal of the contaminants by the activated carbon may not be sufficient. When an amount of the phosphoric acid-based compound is about 5 wt% to about 15 wt%, removal efficiency of contaminants may be improved, and a retention period of the filter may be excellent.

The activated carbon on which the phosphoric acid-based compound is supported, included in the first adsorption layer 136, may have a particle size of about 20 mesh to about 60 mesh. The smaller the particle size of the activated carbon, the more advantageous removal of contaminants at a low concentration. The larger the particle size of the activated carbon, the more advantageous removal of the contaminants at a high concentration. Since the particle size of the activated carbon included in the first adsorption layer 136 has the above-described range, low molecular weight silicon-based contaminants such as TMS or the like included in gas may be efficiently removed.

The activated carbon on which the phosphoric acid-based compound is supported, included in the first adsorption layer 136, may have a pore size of about 5 Å to about 20 Å. Since a size of TMS may be about 4.2 Å to about 4.9 Å, the activated carbon may have a pore size similar to or larger than that of the TMS. When a pore size of the activated carbon is about 5 Å or more, the TMS may be easily adsorbed into pores of the activated carbon. When a pore size of the activated carbon is 20 Å or less, it is possible to reduce the TMS passing through the pores without being adsorbed to the pores.

The activated carbon on which the phosphoric acid-based compound is supported, included in the first adsorption layer 136, may have a specific surface area of about 1,000 m²/g to 3,000 m²/g. When the specific surface area of the activated carbon is within the above range, adsorption efficiency of contaminants in air by the activated carbon may be improved. Therefore, removal efficiency of the contaminants by the filter may be improved.

A type and a shape of the activated carbon included in the first adsorption layer 136 are not limited. The activated carbon may include, for example, palm-based activated carbon, coal-based activated carbon, and the like. The activated carbon may have a granular shape, a spherical shape, or a pellet shape. In an example embodiment, the activated carbon may include palm-based activated carbon.

Gas flowing into the scanner 220 may further include other contaminants, in addition to TMS. In an example embodiment, the gas may include TMS, toluene (or other organic solvent), perfluorotripropylamine (or other amines such as other fluorinated or non-fluorinated alkylamines), and the like (or other contaminants depending upon the process being performed). The above-mentioned contaminants may be adsorbed by the activated carbon of the first adsorption layer 136. TMS, which has the smallest size among the aforementioned contaminants, may be easily desorbed from the first adsorption layer 136.

A filter 130 according to example embodiments of the present inventive concept may include the second adsorption layer 139 disposed on the first adsorption layer 136, and TMS desorbed or not adsorbed from the first adsorption layer 136 may be removed secondarily.

The second adsorption layer 139 may adsorb and remove contaminants in air, together with the first adsorption layer 136. The second adsorption layer 139 may assist the first adsorption layer 136, to improve durability and lifespan of the gas purifying filter 130.

The second adsorption layer 139 may include a hydrophobic zeolite. Unlike a hydrophilic zeolite, the hydrophobic zeolite may not react with water vapor contained in the harmful gas. Therefore, since the water vapor contained in the harmful gas would react with the zeolite first, a problem of not reacting with other harmful gases such as TMS or the like may be effectively prevented.

A SiO₂/Al₂O₃ value of the hydrophobic zeolite included in the second adsorption layer 139 may be about 50 or more. The second adsorption layer 139 may be, for example, a Y-type zeolite. When the SiO₂/Al₂O₃ value of the zeolite has the above range, reactivity of the zeolite with water vapor may be reduced. Therefore, a problem that the reactivity with harmful gases is reduced may be effectively prevented. The SiO₂/Al₂O₃ value of the hydrophobic zeolite included in the second adsorption layer 139 may be, for example, about 75 or more, e.g. 100 or more. The second adsorption layer 139 may be a beta zeolite. In an example embodiment, the second adsorption layer 139 may include at least one of a Y-type zeolite or a beta zeolite.

A pore size d2 of a zeolite included in the second adsorption layer 139 may be about 5 Å or more and about 20 Å or less. When the pore size of the zeolite satisfies the above range, as illustrated in FIG. 3, a contaminant PL may be easily adsorbed into a pore of a zeolite ZL. As a size d1 of the contaminant, for example, TMS is from about 4.2 Å to about 4.9 Å. In an example embodiment, the pore size d2 of the zeolite included in the second adsorption layer 139 may be about 5 Å or more and about 8 Å or less.

A weight of the activated carbon on which the phosphoric acid-based compound is supported may be about 80 to about 95 wt%, based on a total weight of the activated carbon on which the phosphoric acid-based compound is supported and the hydrophobic zeolite. A weight of the hydrophobic zeolite may be about 5 to about 20 wt%, based on the total weight of the activated carbon on which the phosphoric acid-based compound is supported and the hydrophobic zeolite. By satisfying the above range, TMS, toluene, and perfluorotripropylamine contained in the harmful gas, accommodated in the lower plenum chamber (100 in FIG. 1) and moved to the path of F9, may be sufficiently adsorbed on the activated carbon of the first adsorption layer 136, and TMS desorbed from the activated carbon may be adsorbed to the hydrophobic zeolite of the second adsorption layer 139, to improve selective removal efficiency of TMS.

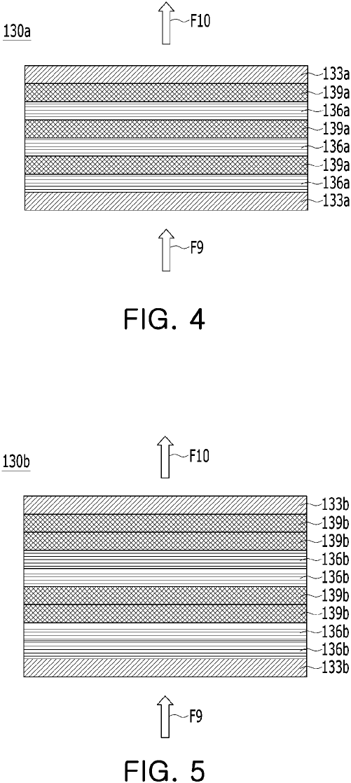

FIGS. 4, 5, 6, and 7A to 7C are views illustrating a gas purifying filter according to example embodiments. In the embodiments of FIGS. 4 to 7C, reference numerals identical to and letters different from those of FIG. 3 may be used to describe an embodiment different from those of FIG. 3. Features described with the same reference numerals described above may be the same or similar.

Referring to FIG. 4, it may be different from the embodiment of FIG. 3 in view of the facts that a gas purifying filter 130a includes first adsorption layers 136a and second adsorption layers 139a, alternately disposed between first and second air permeable bodies 133a.

Harmful gas may flow into the first gas permeable body 133a (F9), and may pass through a plurality of first and second adsorption layers 136a and 139a alternately, to be discharged through the second gas permeable body 133a (F10).

TMS, not be adsorbed by the first adsorption layer 136a or desorbed from the first adsorption layer 136a after being adsorbed thereon, may be re-adsorbed on and removed from the second adsorption layer 139a. The gas purifying filter 130a may include a plurality of first and second adsorption layers 136a and 139a, to increase re-adsorption frequency of TMS. Therefore, removal efficiency of the TMS by the gas purifying filter 130a may be improved.

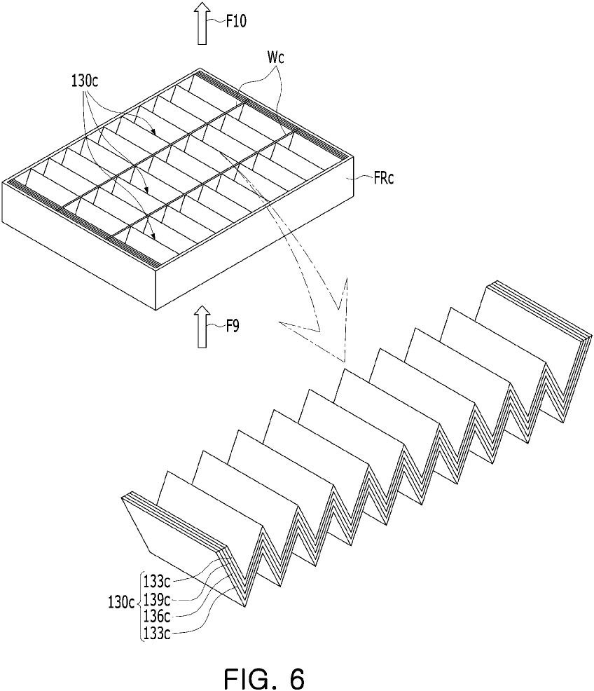

Referring to FIG. 5, it may be different from the embodiment of FIG. 3 in view of the facts that a gas purifying filter 130b includes a plurality of first adsorption layers 136b and a plurality of second adsorption layers 139b between the first and second air permeable bodies 133b. It may be different from the embodiment of FIG. 4 in view of the facts that, in the gas purifying filter 130b of FIG. 5, each of the first adsorption layers 136b and the second adsorption layers 139b are sequentially disposed.

The gas purifying filter 130b may include a portion in which the first and second adsorption layers 136b and 139b are continuously stacked, to increase an amount of TMS that may be removed from each of the adsorption layers. As illustrated in FIG. 5, after adsorbing a large amount of TMS in two consecutive first adsorption layers 136b, TMS desorbed from the first adsorption layers 136b may be re-absorbed in two consecutive second adsorption layers 139b. Therefore, removal efficiency of the TMS by the gas purifying filter 130b may be improved.

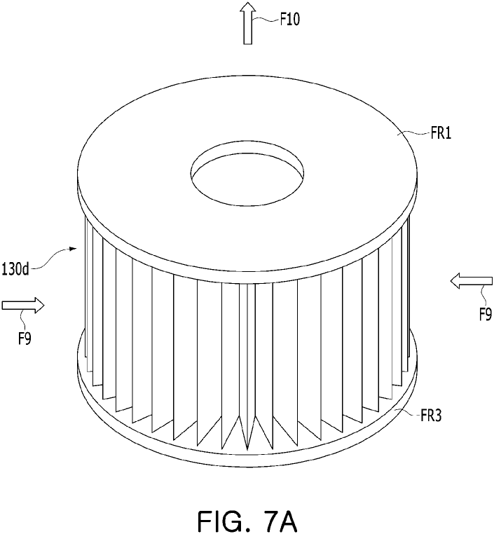

Referring to FIG. 6, it may be different from the above embodiments in view of the facts that a gas purifying filter 130c has a zigzag shape.

As illustrated in FIG. 6, the gas purifying filter 130c may have a structure in which a first gas permeable body 133c, a first adsorption layer 136c, a second adsorption layer 139c and a second gas permeable body 133c, each having a zigzag shape, are stacked. Since the gas purifying filter 130c has a zigzag shape, a contact area with harmful gas may increase. Therefore, removal efficiency of contaminants in the harmful gas may be improved. A shape of the gas purifying filter 130c is not limited to a zigzag shape, and may have another shape (e.g., a wavy shape) capable of improving a contact area with gas.

The gas purifying filter 130c may be disposed as one or more gas purifying filters 130c in a frame FRc. When a plurality of gas purifying filters 130c is disposed, the gas purifying filters 130c may be supported by a frame FRc and walls Wc. A shape of the frame FRc, the number of the walls Wc, or the like may be changed. For example, the frame FRc may further include a mesh-type plate disposed on upper and lower surfaces of the frame FRc, perpendicular to inflow and outflow directions of air.

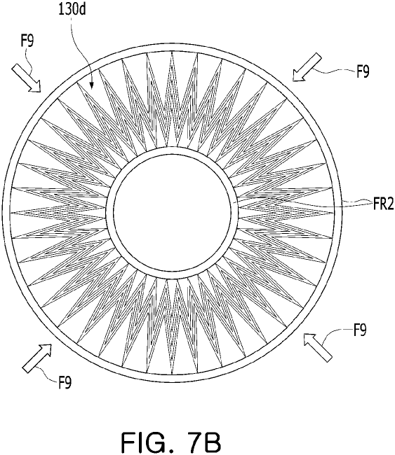

FIG. 7A is a perspective view illustrating a gas purifying filter according to example embodiments, FIG. 7B is a cross-sectional view illustrating a gas purifying filter according to example embodiments, and FIG. 7C is a partial perspective view illustrating a gas purifying filter according to example embodiments.

Referring to FIGS. 7A to 7C, a gas purifying filter 130d may have a zigzag shape, and may be disposed in a cylindrical frame.

The gas purifying filter 130d may be disposed between external and internal frames FR2. Air may flow through the external frame FR2 (F9). The air may pass through the gas purifying filter 130d, and may flow out through an upper frame FR1 (F10). In an example embodiment, the external and internal frames FR2 and the upper frame FR1 may be mesh-type plates through which gas passes. In an example embodiment, a lower frame FR3 may be a plate through which gas cannot pass.

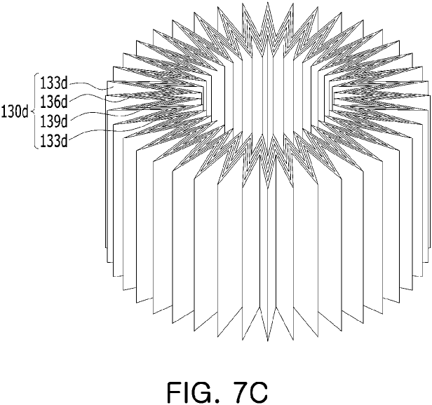

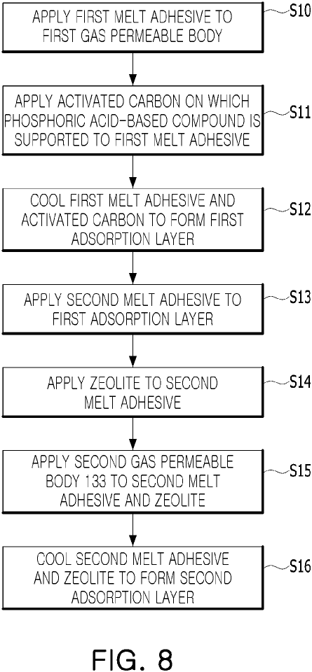

FIGS. 8 and 9 are flowcharts illustrating a method of manufacturing a gas purifying filter according to example embodiments. FIGS. 8 and 9 illustrate a method of manufacturing the gas purifying filter 130 of FIG. 3, respectively.

Referring to FIG. 8 together with FIG. 3, a first melt adhesive may be applied to a first gas permeable body 133 (S10).

The first melt adhesive may have a melting point of from about 40° C. to about 140° C. The first melt adhesive may include, for example, one or more of ethylene vinyl acetate, polypropylene, polyethylene, polystyrene, polyisopropylene, and sterene-i sopropylene.

Activated carbon on which a phosphoric acid-based compound is supported may be applied to the first melt adhesive (S11).

The first melt adhesive and the activated carbon may be cooled to form a first adsorption layer 136 (S12). Durability of the first adsorption layer 136 and adhesion of the first adsorption layer 136 to the first gas permeable body 133 may be improved by the cooled first melt adhesive, to improve stability of a gas purifying filter 130.

A second melt adhesive may be applied to the first adsorption layer 136 (S13).

The second melt adhesive may have a melting point of from about 40° C. to about 140° C. The second melt adhesive may include, for example, one or more of ethylene vinyl acetate, polypropylene, polyethylene, polystyrene, polyisopropylene, and sterene-isopropylene. The second melt adhesive may include the same or a different material as the first melt adhesive.

A hydrophobic zeolite may be applied to the second melt adhesive (S14).

A second gas permeable body 133 may be applied to the second melt adhesive and the hydrophobic zeolite (S15).

The second melt adhesive and the zeolite may be cooled to form a second adsorption layer 139 (S16). Since the second adsorption layer 139 may include the second melt adhesive, impact resistance and durability of the gas purifying filter 130 may be improved.

The gas purifying filter 130 illustrated in FIG. 3 may be manufactured by performing S10 to S16 described above.

Next, referring to FIG. 9 together with FIG. 3, activated carbon on which a phosphoric acid-based compound is supported may be dissolved in a first solvent to generate a first solution (S20).

The activated carbon on which the phosphoric acid-based compound is supported may be prepared by impregnating activated carbon in a solution in which the phosphoric acid-based compound is dissolved, and drying and sintering the same.

The impregnation may be performed by adding activated carbon to a solution in which the phosphoric acid-based compound is dissolved, and then leaving the same at room temperature for about 30 minutes to about 2 hours.

The drying may be performed by leaving the activated carbon-impregnated solution at a temperature of about 90° C. to about 120° C. for about 10 hours to about 15 hours.

The sintering may be performed by leaving the dried activated carbon at a temperature of about 150° C. to 450° C. The sintering may be performed at a temperature in the above range, to uniformly support the phosphoric acid-based compound on the activated carbon, and to reduce an amount of moisture contained in the activated carbon. Therefore, lifespan and heat resistance of the gas purifying filter may be improved. A temperature for the sintering may be, for example, from about 300° C. to about 400° C. The sintering may be performed for about 1 hour to about 5 hours.

A method of manufacturing the activated carbon on which the phosphoric acid-based compound is supported is not limited to the above, and a temperature and a time period in each operation may be changed, according to an amount of the activated carbon, a concentration of the phosphoric acid-based compound, or the like.

After applying the first solution generated in S20 on a first gas permeable body 133, the first solvent may be removed to form a first adsorption layer (S21).

A second solution in which a zeolite is dissolved in a second solvent may be generated (S22). S22 may be performed before S20, after S20, before S21, or after S21. An order in which S22 is performed is not limited.

After applying the second solution on the first adsorption layer formed in S21, the second solvent may be removed to form a second adsorption layer 139 (S23).

The gas purifying filter 130 illustrated in FIG. 3 may be manufactured by performing S20 to S23 described above.

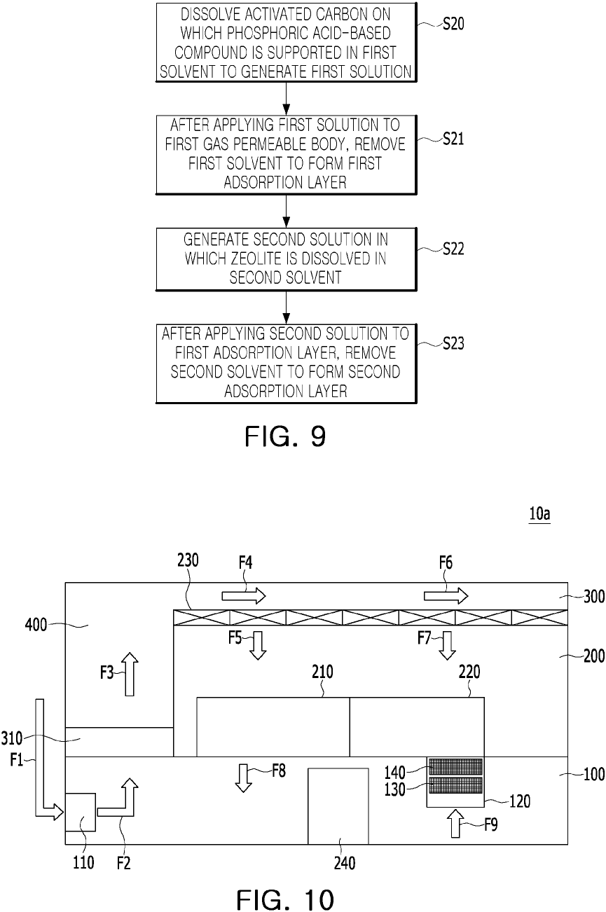

FIG. 10 is a schematic configuration diagram illustrating a substrate treatment apparatus 10a according to example embodiments. In the embodiment of FIG. 10, features described with the same reference numerals described in FIG. 1 may be the same or similar.

A substrate treatment apparatus 10a of FIG. 10 may be different from the substrate treatment apparatus 10 in view of the facts that an organic contamination analyzer 240 is further included in a lower plenum chamber 100.

The organic contamination analyzer 240 may quantitatively or qualitatively measure a concentration of each contaminant included in air. The organic contamination analyzer 240 may measure a first concentration of a contaminant in air of the lower plenum chamber 100, a second concentration of a contaminant in air after passing the air in the lower plenum chamber 100 through a first filter 130 of an air control cabinet 120, and a third concentration of a contaminant in air flowing into a scanner 220. The first to third concentrations may be measured by a sampling tube installed at a position to be measured.

When the first concentration and the second concentration, measured by the organic contamination analyzer 240, are compared, efficiency and lifespan of the first filter 130 may be evaluated. When the second concentration and the third concentration, measured by the organic contamination analyzer 240, are compared, a change amount in contamination of a second filter 140 may be evaluated. By observing the third concentration measured by the organic contamination analyzer 240, a change amount in contamination of a reduction lens (1600 in FIG. 2B) in the scanner 220 may be evaluated.

The substrate treatment apparatus 10a of FIG. 10 may further include an organic contamination analyzer 240 to evaluate efficiency and lifespan of the first and second filters 130 and 140, and to evaluate a degree of contamination of environment of a region on which the lens in the scanner 220 is disposed.

Hereinafter, a gas purification filter according to example embodiments of the present inventive concept will be described in more detail with reference to specific examples. However, the following examples are only illustrative for describing the present inventive concept in more detail, and the present inventive concept is not limited by the following examples.

### Example 1

A polypropylene copolymer was melted and applied to a non-woven fabric. Activated carbon on which phosphoric acid is supported, as illustrated in Table 1 below, was applied to the melted polypropylene copolymer.

Thereafter, the non-woven fabric and the activated carbon were cooled to form a first adsorption layer on the non-woven fabric.

Then, the melted polypropylene copolymer was applied to the first adsorption layer again.

Thereafter, a zeolite illustrated in Table 1 below was applied to the melted polypropylene copolymer, and was covered with another non-woven fabric.

Then, a stack body was cooled to form a second adsorption layer on the first adsorption layer, to manufacture a gas purifying filter.

### Comparative Example 1

A gas purifying filter was manufactured in the same manner as in Example 1, except that a second adsorption layer was not formed and phosphoric acid was not supported on activated carbon of a first adsorption layer.

### Comparative Example 2

A gas purifying filter was manufactured in the same manner as in Example 1, except that a second adsorption layer was not formed.

### Comparative Example 3

A gas purifying filter was manufactured in the same manner as in Example 1, except that a first adsorption layer was not formed.

### Comparative Example 4

A gas purifying filter was manufactured in the same manner as in Example 1, except that a ratio between a first adsorption layer and a second adsorption layer was different.

TABLE 1

| Example | Activated Carbon on which Phosphoric Acid is supported | | Zeolite | | | Amount of Zeolite in Filter (%) |
|---|---|---|---|---|---|---|
| | Pore Size (Å) of Activated Carbon | Amount of which Phosphoric Acid is supported (%) | Type | Pore Size (Å) | SiO₂/Al₂O₃ | |
| Inventive Example 1 | 5 | 10 | Beta Zeolite | 6.5 | 110 | 10 |
| Comparative Example 1 | 5 | 0 | - | - | - | 0 |
| Comparative Example 2 | 5 | 10 | - | - | - | 0 |
| Comparative Example 3 | - | - | Beta Zeolite | 6.5 | 110 | 100 |
| Comparative Example 4 | 5 | 10 | Beta Zeolite | 6.5 | 110 | 30 |

For Inventive Example 1 and Comparative Examples 1 to 4, the following Experimental Examples 1 to 4 were performed.

In Experimental Examples 1 and 2, in order to confirm TMS adsorption performance in a complex gas environment, a complex gas of TMS, toluene, and perfluorotripropylamine was injected at high and low concentrations, respectively, with respect to Inventive Example 1 and Comparative Example 1, to evaluate breakthrough time.

### Experimental Example 1

The gas purifying filters of Inventive Example 1, Comparative Example 1, and Comparative Example 4 were cut to have a circular shape with a diameter of about 5 cm, and concentration conditions into which TMS, toluene and perfluorotripropylamine were lead in a respective amount of 10 ppm were set, under conditions of a temperature of 23° C. and a relative humidity of 45%. Then, adsorption performance of each of the gas purifying filters of Inventive Example 1, Comparative Example 1, and Comparative Example 4 was evaluated.

Time periods ranging, from time at which harmful gas starts to pass through each of the gas purifying filters of Inventive Example 1, Comparative Example 1, and Comparative Example 4, to time at which breakthrough and removal efficiency reach 90% (hereinafter, ‘breakthrough time’), were measured and illustrated in Table 2 below.

### Experimental Example 2

The gas purifying filters of Inventive Example 1, Comparative Example 1 and Comparative Example 4 were cut to have a circular shape with a diameter of about 5 cm, and concentration conditions into which TMS was lead in an amount of 10 ppm, and toluene and perfluorotripropylamine were lead in a respective amount of 50 ppm were set, under conditions of a temperature of 23° C. and a relative humidity of 45%. Then, adsorption performance of each of the gas purifying filters of Inventive Example 1, Comparative Example 1, and Comparative Example 4 was evaluated.

Breakthrough times of Inventive Example 1, Comparative Example 1, and Comparative Example 4 were measured and illustrated in Table 2 below.

TABLE 2

| Example | Experimental Example 1 (Low Concentration Complex Gas) | | | Experimental Example 2 (High Concentration Complex Gas) | | |
|---|---|---|---|---|---|---|
| | TMS Breakthrough Time (min.) | Toluene Breakthrough Time (min.) | Perfluorotripropylamine Breakthrough Time (min.) | TMS Breakthrough Time (min.) | Toluene Breakthrough Time (min.) | Perfluorotripropylamine Breakthrough Time (min.) |
| Inventive Example 1 | 640 | 730 | 710 | 150 | 180 | 110 |
| Comparative Example 1 | 590 | 775 | 750 | 110 | 190 | 120 |
| Comparative Example 4 | 550 | 630 | 550 | 130 | 170 | 100 |

Next, in Experimental Examples 3 and 4, in order to compare and confirm adsorption performance of activated carbon on which a phosphoric acid-based compound was supported, adsorption performance of activated carbon on which a phosphoric acid-based compound is not supported, and adsorption performance of a zeolite, for harmful gas, experiments for Comparative Examples 1 to 3 were performed.

### Experimental Example 3

Concentration conditions into which TMS was lead in an amount of 10 ppm into 20 cc of the gas purifying filters of Comparative Examples 1 to 3 was set, under conditions of a temperature of 23° C. and a relative humidity of 45%. Then, adsorption performance of Comparative Examples 1 to 3 was evaluated.

Breakthrough times of Comparative Examples 1 to 3 were measured and are illustrated in Table 3 below.

### Experimental Example 4

Concentration conditions into which TMS and toluene were lead in a respective amounts of 10 ppm into 20 cc of the gas purifying filters of Comparative Examples 1 to 3 was set, under conditions of a temperature of 23° C. and a relative humidity of 45%. Then, adsorption performance of Comparative Examples 1 to 3 was evaluated.

Breakthrough times of Comparative Examples 1 to 3 were measured and illustrated in Table 3 below.

TABLE 3

| Example | In evaluation of TMS only, Breakthrough Time (min.) | In combined evaluation of TMS and Toluene | |
|---|---|---|---|
| | | TMS Breakthrough Time (min.) | Toluene Breakthrough Time (min.) |
| Comparative Example 1 | 660 | 230 | 430 |
| Comparative Example 2 | 1,100 | 660 | 440 |
| Comparative Example 3 | 320 | 270 | 50 |

Referring to Tables 2 and 3, Inventive Example 1 exhibited superior breakthrough time, compared to Comparative Examples in which no phosphoric acid-based compound was supported on activated carbon or in which only one of the first adsorption layer or the second adsorption layer was included.

In addition, when comparing Inventive Example 1 and Comparative Example 4 in which a ratio between the activated carbon on which a phosphoric acid-based compound was supported and the zeolite was different, Inventive Example 1 having an optimal adsorption ratio had a high TMS breakthrough time, and thus was confirmed to have excellent filter performance.

Referring to Table 3, in evaluation of TMS only, the breakthrough time was excellent in the order of the activated carbon on which a phosphoric acid-based compound was supported (Comparative Example 2), the activated carbon on which a phosphoric acid-based compound was not supported (Comparative Example 1), and the zeolite (Comparative Example 3).

In combined evaluation of TMS and toluene, the TMS breakthrough time was excellent in the order of the activated carbon on which a phosphoric acid-based compound was supported (Comparative Example 2), the zeolite (Comparative Example 3), and the activated carbon on which a phosphoric acid-based compound was not supported (Comparative Example 1).

The zeolite (Comparative Example 3) had a smaller specific surface area, compared to the activated carbon on which a phosphoric acid-based compound was not supported (Comparative Example 1), and a TMS adsorption amount was small in Experimental Example 3 in which only TMS was evaluated.

In combined evaluation of TMS and toluene, a TMS adsorption amount of the zeolite (Comparative Example 3) increased, compared to a TMS adsorption amount of the activated carbon on which a phosphoric acid-based compound was not supported (Comparative Example 1). Since the zeolite (Comparative Example 3) has pores having a size similar to that of toluene, a toluene adsorption amount of the zeolite (Comparative Example 3) decreased, and the TMS adsorption amount of the zeolite (Comparative Example 3) increased. For this reason, the TMS adsorption amount of the zeolite (Comparative Example 3) increased, compared to that of the activated carbon on which a phosphoric acid-based compound was not supported (Comparative Example 1).

From this, it can be confirmed that, when activated carbon on which a phosphoric acid-based compound is supported and a zeolite are used simultaneously in a complex gas environment, TMS may be selectively adsorbed, compared to when activated carbon on which a phosphoric acid-based compound is not supported is used.

According to the present inventive concept, inflow of contaminants into a semiconductor manufacturing facility may be prevented. For example, inflow of volatile organic compounds (VOC) such as trimethylsilane or the like into a photo-scanner facility may be prevented.

Various advantages and effects of the present inventive concept are not limited to the above, and will be more easily understood in the process of describing specific embodiments of the present inventive concept.

While example embodiments have been illustrated and described above, it will be apparent to those skilled in the art that modifications and variations could be made without departing from the scope of the present inventive concept as defined by the appended claims.

What is claimed is:

1. A gas purifying filter comprising:
a first gas permeable body having a gas inlet surface;
a first adsorption layer disposed on the first gas permeable body and including activated carbon on which a phosphoric acid-based compound satisfying the following Formula 1 is supported, 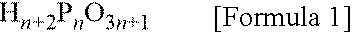
where n is an integer greater than or equal to 1;
a second adsorption layer disposed on the first adsorption layer and including a hydrophobic zeolite having a SiO₂/Al2O₃ value of about 50 or more; and
a second gas permeable body disposed on the second adsorption layer and having a gas outlet surface.

2. The gas purifying filter of claim 1, wherein the activated carbon on which the phosphoric acid-based compound is supported comprises from about 5 to about 15 wt% of the phosphoric acid-based compound with respect to 100 wt% of the activated carbon.

3. The gas purifying filter of claim 1, wherein a particle size of the activated carbon is about 20 to about 60 mesh.

4. The gas purifying filter of claim 1, wherein a pore size of the activated carbon is about 5 to about 20 Å.

5. The gas purifying filter of claim 1, wherein a pore size of the hydrophobic zeolite is about 5 to about 8 Å.

6. The gas purifying filter of claim 1, wherein the hydrophobic zeolite comprises at least one of a beta zeolite or a Y zeolite.

7. The gas purifying filter of claim 1, wherein at least one of the first adsorption layer or the second adsorption layer further comprises an adhesive.

8. The gas purifying filter of claim 7, wherein the adhesive has a melting point of about 40 to about 140° C.

9. The gas purifying filter of claim 7, wherein the adhesive comprises at least one of ethylene vinyl acetate, polypropylene, polyethylene, polystyrene, polyisopropylene, or sterene-isopropylene.

10. The gas purifying filter of claim 1, wherein the first gas permeable body and the second gas permeable body comprise a non-woven fabric.

11. The gas purifying filter of claim 1, wherein gas flowing into the gas inlet surface of the first gas permeable body comprises at least one of trimethylsilanol, toluene, or perfluorotripropylamine.

12. The gas purifying filter of claim 1, wherein the activated carbon on which the phosphoric acid-based compound is supported comprises about 80 to about 95 wt%, based on a total weight of the activated carbon on which the phosphoric acid-based compound is supported and the hydrophobic zeolite, and
the hydrophobic zeolite comprises about 5 to about 20 wt%, based on the total weight of the activated carbon on which the phosphoric acid-based compound is supported and the hydrophobic zeolite.

13. The gas purifying filter of claim 1, comprising a plurality of the first adsorption layer and a plurality of the second adsorption layer disposed between the first gas permeable body and the second gas permeable body,
wherein the first adsorption layers and the second adsorption layers are alternately stacked.

14. A substrate treatment apparatus comprising:
a working region accommodating a spinner and a scanner;
a lower plenum chamber disposed below the working region and accommodating exhaust gas discharged from the spinner; and
an air control cabinet disposed in the lower plenum chamber below the scanner and including a first filter,
wherein the first filter comprises:
a first gas permeable body having a gas inlet surface;
a first adsorption layer disposed on the first gas permeable body and including activated carbon on which a phosphoric acid-based compound satisfying the following Formula 1 is supported;
a second adsorption layer disposed on the first adsorption layer and including a hydrophobic zeolite having a SiO₂/Al₂O₃ value of about 50 or more; and
a second gas permeable body disposed on the second adsorption layer and having a gas outlet surface. 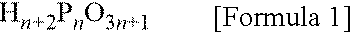
where n is an integer greater than or equal to 1.

15. The substrate treatment apparatus of claim 14, wherein at least a portion of air accommodated in the lower plenum chamber passes through the air control cabinet and flows into the scanner.

16. The substrate treatment apparatus of claim 14, wherein the air control cabinet further comprises a second filter disposed on the first filter,
wherein the second filter comprises at least one of activated carbon or an ion exchange resin.

17. The substrate treatment apparatus of claim 14, further comprising:
an upper plenum chamber disposed on the working region and connected to the working region;
a circulation passage disposed on at least one side of the working region and connecting the lower plenum chamber and the upper plenum chamber; and
a dry coil disposed between the lower plenum chamber and the circulation passage.

18. The substrate treatment apparatus of claim 17, wherein the exhaust gas discharged from the spinner into the lower plenum chamber passes through the dry coil and is accommodated in the upper plenum chamber.

19. The substrate treatment apparatus of claim 18, wherein the working region further comprises an upper filter disposed in an upper portion of the working region,
wherein air accommodated in the upper plenum chamber passes through the upper filter and flows into the working region.

20. The substrate treatment apparatus of claim 14, further comprising an air inlet introducing fresh air into the lower plenum chamber from an outside of the lower plenum chamber.

21-23. (canceled)
